(19) United States
(12) Patent Application Publication
(10) Pub. No.: US 2010/0092692 A1
(43) Pub. Date: Apr. 15, 2010

(54) METHOD AND DEVICE FOR COATING SUBSTRATES

(75) Inventors: Karl-Heinz Dulle, Olfen (DE); Ulf-Steffen Baeumer, Unna (DE); Randolf Kiefer, Gelsenkirchen (DE); Peter Woltering, Neuenkirchen (DE); Dirk Hoormann, Werne A.D. Lippe (DE); Stefan Oelmann, Herner (DE); Joachim-H. Hoedtke, Moorrege/Klevendeich (DE); Oliver Kayser, Lohmar (DE)

Correspondence Address: MARSHALL & MELHORN, LLC, FOUR SEAGATE - EIGHTH FLOOR, TOLEDO, OH, 43604, US

(73) Assignee: UHDE GMBH, DORTMUND (DE)

(21) Appl. No.: 12/312,999

(22) PCT Filed: Nov. 15, 2007
(86) PCT No.: PCT/EP2007/009862

§ 371 Date: Sep. 15, 2009

(30) Foreign Application Priority Data
Dec. 4, 2006 (DE) 10-2006-057-386.2

(51) Int. Cl. C23C 16/50; C23C 16/00; C23C 14/34

(52) U.S. Cl. 427/535; 118/723 R; 204/192.15; 204/298.02; 204/298.09

(57) ABSTRACT

The invention relates to a method for coating one or more sides of substrates with catalytically active material, comprising material deposition under vacuum in a vacuum chamber, wherein the following steps are performed: (a) loading the vacuum chamber with at least one substrate, (b) closing and evacuating the vacuum chamber, (c) cleaning the substrate by introducing a gaseous reducing agent into the vacuum chamber, (d) increasing the size of the substrate surface by depositing a vaporous component on the substrate surface, (e) coating by a coating process taken from the group of plasma coating processes, physical gas deposition, sputtering processes or the like, wherein one or more metals and/or alkaline and/or earth alkaline metals or their oxides are applied to the surface of the substrate. This method may be used, for example, for coating electrodes which are used in the chlor-alkali electrolysis.

The invention relates to a method for coating one or more sides of substrates with catalytically active material, comprising material deposition under vacuum in a vacuum chamber, wherein the following steps are performed:
(a) loading the vacuum chamber with at least one substrate,
(b) closing and evacuating the vacuum chamber,
(c) cleaning the substrate by introducing a gaseous reducing agent into the vacuum chamber,
(d) increasing the size of the substrate surface by depositing a vaporous component on the substrate surface,
(e) coating by a coating process taken from the group of plasma coating processes (PVD processes), physical gas deposition, sputtering processes or the like, wherein one or more metals and/or alkaline and/or earth alkaline metals or their oxides are applied to the surface of the substrate.
This method and the related device may be used, for example, for coating electrodes which are used in the chlor-alkali electrolysis.

Electrodes used in the chlor-alkali electrolysis are to be coated with a catalytically active layer. Such coating is implemented by established spray, immersion or mechanical application processes. EP 0546 714 B1 discloses such a coating process in which the catalyst is applied as a moist mass by means of a spray gun and then heated in an inert gas atmosphere.

According to WO 96/24705 A1 the coating of a cathode is performed by the Physical Vapour Deposition Process (PVD process), wherein a plurality of targets in a vacuum chamber may be used. “Target” in this context is to be understood as a material body which is evaporated, the evaporated material of which being deposited exactly on the substrate. DE 20 2005 011 974 U1, DE 297 14 532 U1 and DE 699 26 634 T2 describe conventional embodiments of such targets. WO 96/24705 A1 suggests cleaning and etching with acid as pre-treatment steps and drying as subsequent step. This wet chemical step prior to vacuum coating requires considerable expenditure in the case of larger-sized components and the necessary drying makes the process more complicated. Decisive, however, is that the quality of the surface and/or its coating is subject to strong variations in the case of large substrate elements and an adequate reproducibility is not yet ensured.

EP 0 099 867 A1 discloses a cathode which is coated with catalyst by sputtering under vacuum. Prior to coating, the surface is increased in size and roughened by sand-blasting. The disadvantage involved in the sand-blasting is that, in the case of planar substrates, it is difficult to reproduce the degree and the uniform distribution of the surface roughness and difficult to adjust them across the entire substrate. The reachable structural shaping of the surface is limited since, from a certain point, produced peaks will be levelled again after a prolonged period of impact.

According to the state of the art there is the problem to provide an unsophisticated and well-reproducible method for the coating of substrates and especially electrodes. This aim is achieved by the method according to the present invention for coating one or more sides of substrates with a catalytically active material, consisting in a material deposition process under vacuum in a vacuum chamber.

This method is characterised by performing the following steps:
(a) loading the vacuum chamber with at least one substrate,
(b) closing and evacuating the vacuum chamber,
(c) cleaning the substrate by introducing a gaseous reducing agent into the vacuum chamber,
(d) increasing the size of the substrate surface by depositing a vaporous component on the substrate surface, which, in the ideal case, is identical with the material of the substrate, ideally applying plasma evaporation,
(e) coating by a coating process taken from the group of plasma coating processes, physical gas deposition, sputtering processes or the like, wherein one or more metals or their oxides are applied to the surface of the substrate,
(f) flooding the vacuum chamber and removing the coated substrate.

The before-mentioned steps and changes from one step to the next may be performed under vacuum by applying different pressures if required. Thus the substrate never leaves the vacuum and the formation of oxidic intermediate layers or the deposit of new dirt is successfully prevented. Furthermore, the before-mentioned deposition method under vacuum serves to produce a homogeneous substrate surface that can be reproduced at any time.

The deposition processes selected in step d) involve the great advantage that the surface is not covered and the existing, intended roughness is thus not levelled again but insular, spotted peaks are generated which constitute an actual surface enlargement and provide excellent adhesive conditions for the subsequent rather planar layer. The materials to be deposited on the substrate can be selected freely and depend on the intended use of the substrate. In the case of the above-mentioned electrodes it is of advantage to coat the substrate in coating step (e) also with other materials or material mixtures, wherein these materials, in the ideal case, are rare earths or contain the latter.

This deposition method under vacuum involves the additional advantage that it is possible to apply the materials to be deposited in very low concentrations, which, if applied by conventional wet-thermal processes, cannot be distributed over surfaces in a homogeneous manner and of reproducible equal quality.

A process embodiment consists in introducing an oxidising gas into the vacuum chamber directly subsequent to the coating step (e) to produce a defined metal oxide layer.

An improved process embodiment provides for coating the substrate with one or more non-oxidic metals and/or alkaline and/or earth alkaline metals in the coating step (e), while introducing an oxidising gas into the vacuum chamber during the whole or part of the coating period. For this purpose, the oxidising gas, which may be oxygen or an oxygen-containing gas, is introduced in a pulsed manner into the vacuum chamber. The surprising result has been that a durable coating of exceptionally high quality can thus be achieved as well as intermetal oxide layers and/or disintegrations very efficiently be avoided.

The method can be improved in such a way that the coating step (e) or the removing step (f) is followed by a thermal treatment of the coated substrates at a temperature between 350° C. and 650° C. This thermal treatment, in which intercrystalline processes take place that shall here not be described in more detail, will improve the long-term bonding strength of the coating.

The coating method may be complemented in such a way that—under atmospheric conditions and prior to the first step (a)—one or more process steps for the increase of the size of the surface, structural shaping and/or cleaning of the surface are performed. In the ideal case, mechanical processes such as a sandblasting process and/or a chemical process such as an etching process, for example, are used for this purpose. Depending on the previously applied treatment, the substrate surface is subsequently cleaned for the first time and/or dried.

A special process embodiment refers to the breakdown of the process into stages to account for the different duration of the individual process steps. In this embodiment
(a) a pre-chamber is loaded with a plurality of substrates in a first stage.
(b) In a second stage a single or a few substrates taken from the pre-chamber are positioned in the vacuum chamber and subsequently at least process step (e) is implemented. Ideally all vacuum steps, i.e. process steps (c) to (e) are carried out in this second step.
(c) Subsequently, in a third stage, the coated substrates are collected in an unloading chamber and removed from time to time, wherein the three chambers can be separated from each other by valves or locks.

This embodiment can be improved by making it possible to adjust the pressure in the three stages and/or chambers independently of each other. Furthermore it is of advantage if the pre-chamber and the unloading chamber can physically be separated from the vacuum chamber. In this way, it is possible to decouple the process steps before and after the coating step. To evacuate large volumes to a pressure of approx. 10⁻⁵ bar and below is very time-consuming. Such an evacuation period is even prolonged if contaminants and/or moisture get into the chamber, which result from an upstream wet cleaning step such as an etching and/or washing process, for example.

In a process embodiment, the evacuation of one or more pre-chambers and/or the unloading chamber can be done independently in terms of place and/or time from the actual surface treatment of the substrate or the substrates. After connecting the pre-chamber and/or the unloading chamber it is thus only required to evacuate the small volume between these chambers and the treatment chamber. This transitory volume in the area of the gaskets and valves or locks is very small in comparison to the chamber volumes and hence only little time is required to generate a vacuum which is identical to that of the chambers or to generate the identical pressure.

In this process embodiment the following steps are performed according to the below or a reasonable analogous sequence:
(i) loading the empty pre-chamber with substrates,
(ii) closing the loaded pre-chamber,
(iii) evacuating the pre-chamber and the unloading chamber,
(iv) transporting the pre-chamber and the unloading chamber to the vacuum chamber,
(v) connecting the pre-chamber and the unloading chamber mechanically with the vacuum chamber,
(vi) evacuating the volumes enclosed by the locks,
(vii) opening the locks between the pre-chamber or the unloading chamber and the vacuum chamber,
(viii) removing one substrate or an adequate number of substrates and positioning it or them in the vacuum chamber,
(ix) performing at least process step (e), ideally process steps (c) to (e),
(x) removing the substrate from the vacuum chamber and positioning it in the unloading chamber,
(xi) repeating steps (viii) to (x) several times,
(xii) closing the locks between pre-chamber or unloading chamber and vacuum chamber,
(xiii) flooding the volumes enclosed by the locks,
(xiv) decoupling the pre-chamber and the unloading chamber from the vacuum chamber,
(xv) removing the empty pre-chamber and the loaded unloading chamber,
(xvi) flooding the empty pre-chamber,
(xvii) flooding the loaded unloading chamber,
(xviii) removing the substrates,
(xix) starting over from step (i).

The method can be improved by carrying out the before-mentioned thermal process step under vacuum, prior to process step (xvii) in the unloading chamber which has not yet been opened. In the ideal case, steps (i) to (iii) and steps (xvi) to (xix) are varied in terms of time and place and/or performed independently of each other depending on the local logistic possibilities.

An advantage is thus involved in the optimum continuous vacuum treatment of the substrates with regard to the process steps substrate cleaning by introducing a gaseous reducing agent into the vacuum chamber, increasing the size of the substrate surface by depositing a vaporous component on the substrate surface and coating by applying a coating method taken from the group of plasma coating processes, physical gas deposition, sputtering processes or the like. Time-consuming evacuation steps are decoupled from the actual substrate treatment under vacuum.

The invention hence also relates to a device which is used to carry out the before-described method according to any of its embodiments.

As central elements this device includes one or several pre-chambers, one or several treatment chambers, one or several unloading chambers as well as locks provided between the respective chambers. In the case of the device according to the present invention, the pre-chamber is provided as a container. In the case of large planar substrates the pre-chamber is provided as a cartridge. The pre-chamber is equipped with devices via which the former can be evacuated independently and is designed for a pressure of at least 10⁻⁷ bar, the vacuum of the treatment step. In the ideal case, the pre-chamber and the unloading chamber are of identical design.

An improvement of the device involves that the locks and/or the volumes enclosed by the locks can be connected to a vacuum line so that it is possible to evacuate the volumes enclosed by the locks separately.

The pre-chamber and the unloading chamber, as mentioned before, can be designed as cartridges. In an improved process embodiment, these cartridges or containers are also suited for storage and transport purposes under vacuum. An improvement involves that the cartridges, preferably, however, the unloading cartridge, are equipped with a heating element, by which the thermal secondary treatment of the substrates can still be performed under vacuum without prior opening of the cartridge. For this purpose, an electric radiant heater is provided ideally inside the cartridge.

Depending on the geometry of the vacuum chamber and of the substrate it may be of advantage to move the substrate and/or the material source in single or multiple rotatory and/or translational motions towards each other during process steps (c), (d) and/or (e) of the method for coating substrates according to the present invention, wherein the material source is the material to be evaporated and deposited (target) on the substrate or a discharge device such as, for example, a nozzle for one or more gaseous reducing agents.

The invention also includes the use of the before-described method and/or device according to any of the mentioned embodiments in the production of electrodes, especially cathodes for the chlor-alkali electrolysis and/or production of hydrogen.

In a test, a nickel cathode of 150×300 mm as described in WO 98/15675 A1 was loaded as substrate into a vacuum chamber. In the chamber, the substrate was supplied with a mixture of argon and hydrogen and thus pre-cleaned. In a first step, the chamber was evacuated (10⁻⁵ bar). Subsequently the oxide layer was reduced by introducing hydrogen at 250-350° C. Then the size of the surface was increased. Elementary nickel served as a material source (target), which corresponded to the material of the substrate. The round Ni targets had a surface of 30 cm². By a plasma process with a 10⁻⁵ bar vacuum and at a temperature of 250-350° C. this nickel was deposited on the substrate until the surface had increased to 50 times the original size.

Subsequently the pre-treated substrate was coated by a PVD process. Ruthenium was deposited from a target for 2 min. and then the Ru coating was oxidised by oxygen introduced into the vacuum chamber under temperature influence to give ruthenium oxide.

In a second test, which was identical with the first test as far as the pre-treatment is concerned, the substrate was coated with elementary ruthenium by the PVD process, wherein oxygen was introduced in a pulsed manner into the vacuum chamber during the whole coating period. The surprising result was that it was thus possible to deposit ruthenium oxide in situ.

The process is characterised by excellent variability. Layer thicknesses of the intermediate layer and the catalyst as well as—if applicable—mixing ratios of catalysts and, in addition, the amount of pulsed oxygen during coating allow to vary the determining parameters with a technical precision which has never been reached before.

1-21. (canceled)

22. A method for coating one or more sides of substrates with catalytically active material, material deposition under vacuum in a vacuum chamber, comprising:
(a) loading the vacuum chamber with at least one substrate,
(b) closing and evacuating the vacuum chamber,
(c) cleaning the substrate by introducing a gaseous reducing agent into the vacuum chamber,
(d) increasing the size of the substrate surface by depositing a vaporous component on the substrate surface, which, in the ideal case, is identical with the material of the substrate, ideally applying plasma evaporation,
(e) coating by a coating process taken from the group of plasma coating processes, physical gas deposition, sputtering processes or the like, wherein one or more metals or their oxides are applied to the surface of the substrate,
(f) in a last step re-flooding the vacuum chamber and removing the coated substrate from the chamber,
wherein the above steps and changes from one step to the next are performed under vacuum applying different pressures if required.

23. The method for coating substrates according to claim 22, comprising reversing the order of steps (c) and (d).

24. The method for coating substrates according to claim 22, wherein at least one process step for the increase of the size of the surface, structural shaping and/or cleaning of the surface is performed under atmospheric conditions prior to step (a), wherein in the ideal case a mechanical process such as a sandblasting process and/or a chemical process such as, for example, an etching process is used and the substrate surface is subsequently cleaned for the first time and/or dried.

25. The method for coating substrates according to claim 22, wherein, in coating step (e), the substrate is also coated with other materials or material mixtures, wherein these materials, in the ideal case, are rare earths or contain the latter.

26. The method for coating substrates according to claim 22, wherein, in the coating step (e), the substrate is coated with one or more non-oxidic metals while introducing an oxidising gas into the vacuum chamber during the whole or part of the coating period.

27. The method for coating substrates according to claim 22, wherein an oxidising gas is introduced into the vacuum chamber directly subsequent to coating step (e).

28. The method for coating substrates according to claim 22, wherein coating step (e) or removing step (f) is followed by a thermal treatment of the coated substrates at a temperature between 350° C. and 650° C.

29. The method for coating substrates according to claim 22, wherein
in a first stage, a pre-chamber is loaded with a plurality of substrates;
in a second stage, a single or a few substrates taken from the pre-chamber are submitted in the vacuum chamber to at least process step (e); and
in a third stage, the coated substrates are collected in an unloading chamber and removed from time to time, wherein all three stages are under vacuum and the chambers can be separated from each other by valves or locks.

30. The method for coating substrates according to claim 29, wherein the pressure in the three stages can be adjusted independently of each other.

31. The method for coating substrates according to claim 29, further comprising:
(i) loading the pre-chamber with substrates;
(ii) closing the loaded pre-chamber;
(iii) evacuating the pre-chamber and the unloading chamber;
(iv) transporting the pre-chamber and the unloading chamber to the vacuum chamber;
(v) connecting the pre-chamber and the unloading chamber mechanically with the vacuum chamber;
(vi) evacuating the volumes enclosed by the locks;
(vii) opening the locks between the pre-chamber or the unloading chamber and the vacuum chamber;
(viii) removing one substrate or an adequate number of substrates and positioning it or them in the vacuum chamber;
(ix) performing at least process step (e);
(x) removing the substrate from the vacuum chamber and positioning it in the unloading chamber;
(xi) repeating steps (viii) to (x) several times;
(xii) closing the locks between pre-chamber or unloading chamber and vacuum chamber;
(xiii) flooding the volumes enclosed by the locks;
(xiv) decoupling the pre-chamber and the unloading chamber from the vacuum chamber;
(xv) removing the empty pre-chamber and the loaded unloading chamber;
(xvi) flooding the empty pre-chamber;
(xvii) flooding the loaded unloading chamber;
(xviii) removing the substrates; and
(xix) starting over from step (i).

32. The method for coating substrates according to claim 22, wherein the substrates are submitted to a thermal treatment subsequent to process step (e), wherein this is ideally carried out by means of an electric radiant heater.

33. The method for coating substrates according to claim 22, wherein the thermal process step is carried out under vacuum and ideally before process step (xvii) according to claim 10 in the unloading chamber which has not yet been opened.

34. The method for coating substrates according to claim 22, wherein in process steps (c), (d) and/or (e) the substrate and/or the material source are moved in single or multiple rotatory and/or translational motions towards each other, wherein the material source is the material to be evaporated and deposited (target) on the substrate or a discharge device such as, for example, a nozzle for one or more reducing agents.

35. A device for coating substrates according to claim 29, wherein this device consists in at least one pre-chamber, at least one treatment chamber and at least one unloading chamber, wherein locks are provided between the individual chambers.

36. A device for coating substrates according to claim 35, wherein the connection between pre-chamber, unloading chamber and treatment chamber can be decoupled, the pre-chamber is designed in the form of a container or cartridge and the unloading chamber is ideally of identical design.

37. The device for coating substrates according to claim 35, wherein the chambers are provided with vacuum lines via which the chambers can be evacuated independently of each other and also in decoupled condition.

38. The device for coating substrates according to claim 35, wherein a line and/or opening is provided at the locks or in the area of the locks via which the volume enclosed by the locks can be evacuated.

39. The device for coating substrates according to claim 35, wherein the pre-chamber or unloading chamber designed as a cartridge or container is suited for storage and transport purposes under vacuum.

40. The device for coating substrates according to claim 35, wherein the pre-chamber of unloading chamber designed as a cartridge or container is equipped with at least one heating element, wherein the heating element is an electric radiant heater in the ideal case.

41. The device for coating substrates according to claim 35, wherein the pre-chamber or unloading chamber designed as a cartridge or container is mechanically connected in a way that the connection can be decoupled very easily, wherein the chambers can be closed in such a way that a pressure prevailing in the chamber is essentially maintained, even if an adjacent chamber is connected or decoupled.
